(19) United States
(12) Patent Application Publication
(10) Pub. No.: US 2019/0216246 A1
(43) Pub. Date: Jul. 18, 2019

(54) COASTER FOR ILLUMINATING A LIQUID RECEPTACLE

(71) Applicant: Livocon Technologies UG, München (DE)

(72) Inventors: Deniz Güvenc, München (DE); Serhan Özhan, München (DE); Martin Ossadnik, München (DE); Christian Reimer, Fahrenzhausen (DE)

(21) Appl. No.: 15/872,217

(22) Filed: Jan. 16, 2018

(51) Int. Cl. A47G 23/03; F21V 23/04; F21S 9/02; H05K 1/03; F21V 19/00; H05K 1/18

(52) U.S. Cl. CPC A47G 23/0309; F21V 23/0442; F21S 9/02; F21Y 2115/10; F21V 19/0025; H05K 1/181; H05K 1/0393

(57) ABSTRACT

A coaster for illuminating a liquid receptacle is disclosed. The coaster includes a light and a pressure-sensitive switch for activating the light when the receptacle is placed on the coaster so as to illuminate the receptacle and its contents. A disc battery is sandwiched between strips of a flexible circuit board so that compression of the strips against the battery causes a completion of the circuit to turn the light on.

### BACKGROUND

The invention relates generally to an apparatus for providing illumination to a liquid in a transparent receptacle. In particular, the invention relates to a coaster with a pressure sensitive switch.

Drink coasters are small mats that are placed under a receptacle containing liquid to protect the surface below the mat from damage. Because of their wide spread use, they are often provided as promotional materials in many different establishments. Typically they are a circular or rectangular piece of inexpensive material that is printed with a logo or other message. Most promotional coasters are intended to be single use and disposable, although they may also be resusable.

One of the main uses of promotional coasters is in clubs, bars and lounges. These are places that are typically frequented at night and dimly lit. Unfortunately, these conditions have a negative impact on the visibility of brandings on drink ware, whether bottles or printed glasses.

Thus, a need exists for brand promotions that provide greater visibility to logos and other messages in a variety of environments. There is a further need for a device that is inexpensive, easy to use and attracts the attention of consumers.

### SUMMARY

The invention in one implementation encompasses a coaster. The coaster includes a light and a mechanism for activating the light when a glass or cup placed on the coaster so as to illuminate the glass and its contents.

### DESCRIPTION OF THE DRAWINGS

Features of example implementations of the invention will become apparent from the description, the claims, and the accompanying drawings in which:

FIGS. 1A and 1B depict upper and lower bodies of a coaster according to the present invention.

FIGS. 2A and 2B depict an electronic device for use with the coaster of FIGS. 1A and 1B.

FIG. 3 depicts another view of the electronic device of FIGS. 2A and 2B.

### DETAILED DESCRIPTION

Reference will now be made in detail to one or more embodiments of the invention. While the invention will be described with respect to these embodiments, it should be understood that the invention is not limited to any particular embodiment. On the contrary, the invention includes alternatives, modifications, and equivalents as may come within the spirit and scope of the appended claims. Furthermore, in the following description, numerous specific details are set forth to provide a thorough understanding of the invention. The invention may be practiced without some or all of these specific details. In other instances, well-known structures and principles of operation have not been described in detail to avoid obscuring the invention.

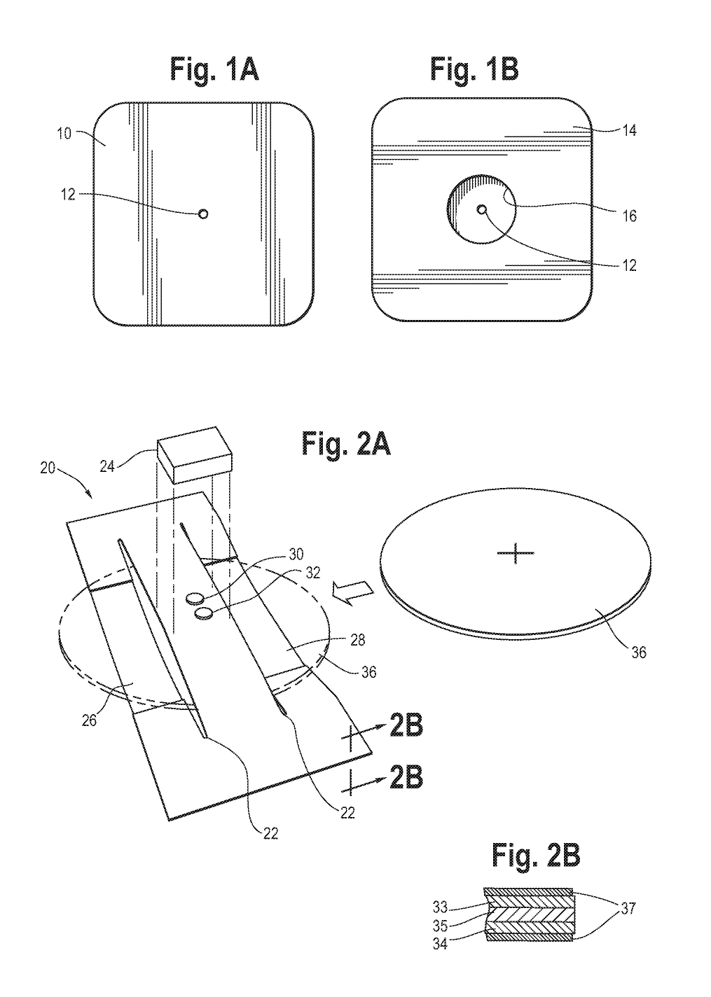

Top and bottom views of a coaster body according to the present invention are shown in FIGS. 1A and 1B. FIG. 1A shows upper body 10. A hole 12 with a diameter of approximately 4 mm is located in the central portion of body 10. This diameter is selected so as to receive an LED (light emitting diode) as explained in further detail below. FIG. 1B shows a lower body 14. A hole 16 with a diameter of approximately 25 mm is located in the central portion of lower body 14. The diameter is selected to receive an electronic device for providing power to the LED. Hole 16 is aligned to have the same center as hole 12.

In an embodiment, the combined upper and lower bodies have a thickness of no more than 3.5 mm in order to provide the pressure sensitive switching functionality described in more detail below. In one embodiment, upper body 10 and lower body 14 are made of two separate pieces of a desired material as shown in FIGS. 1A and 1B, then glued or bonded together. In this embodiment, upper body 10 is approximately 1 mm thick to match the thickness of an LED inserted in hole 12.

In a further embodiment, a coaster body may be made from a single block of material with holes 14 and 16 drilled in from either side. In this embodiment, 4 mm hole 12 would be drilled to a depth of approximately 1 mm. In either embodiment, the upper surface of the coaster body has a completely flat surface so that the LED does not extend above the upper surface. The thickness of upper body 10 and the depth of hole 14 are selected to match the thickness of an inserted LED.

For either of the above embodiments, a thin sheet of paper or similar material is adhered over hole 16 after insertion of the electronic device so as to retain the device within the coaster, although other methods may be used to retain the device within the coaster, for example, directly gluing the device.

The coaster body in either of the above embodiments may be made from a variety of materials such as cardboard, foam or other lightweight materials. At least the upper surface of the body should present a printable surface capable of bearing text and/or images. Although the body of FIGS. 1A and 1B is shown as a square with rounded corners, a coaster body according to the present invention may have any outline, including a standard shapes such as circles as well as other custom, or irregular, outlines.

FIGS. 2A and 2B depict the electronic device of a coaster according to the present invention. FIG. 2A shows an upper side of a flexible circuit board 20. In an embodiment, board 20 is approximately 24 mm long by 8 mm wide, although a variety of dimensions could be used. Two straight cuts 22 are made in the length dimension, dividing board 20 approximately into thirds across its width. LED 24 is mounted on the center strip, in the center of the lengthwise direction as shown. Positive soldering point 30 and negative soldering point 32 are used to attach LED 24 to board 20. In an embodiment, flexible circuit board 20 has several layers, as shown in the inset in FIG. 2A. Two conductive metal layers 33 and 34, for example, copper, separated by a non-conductive layer 35 of polyamide. The upper conductive metal layer 33 serves as the negative pole for electricity, while the bottom conductive metal layer 34 serves as the positive pole. The three layers together are coated with plastic or another non-conductive material 37.

The upper conductive metal layer 33 is exposed in the areas 26 and 28 on the outer strips of board 20, on either side of the center strip holding LED 24, to allow contact to the negative pole of battery 36. The bottom conductive metal layer 34 is exposed in areas 40 and 42 (see FIG. 2B) to allow contact to the positive pole of battery 36. The negative connector of LED 24 connects to the upper conductive metal layer 33 of the circuit board 20. The positive connector connects to the lower conductive metal layer 34 of circuit board 20 using isolated drilling holes. When the inner third of board 20 is separated from the outer thirds as shown, battery 36 is inserted between the strips so that areas 26 and 28 are position to contact the negative pole of battery 36.

The bottom side of board 20 opposite the upper side is shown in FIG. 2B. Straight cuts 22 divide board 20 approximately into thirds as described above. On the bottom side, soldering point 38 is coupled by an isolated drilling hole to soldering point 30 on the upper side of board 20 as shown in FIG. 2A. Soldering points 30 and 38 are coupled to the lower conductive metal layer 34 of board 20. The bottom conductive metal layer 34 of board 20 is exposed in areas 40 and 42. The remaining surface of board 20 is coated with plastic or another non-conductive material. Conductive areas 40 and 42 are positioned to contact the positive pole of battery 36 (FIG. 2A).

Flexible circuit board 20 is manufactured to have enough flexibility to allow the insertion of battery 36 as described above. However, board 20 also has enough stiffness so that when battery 36 is inserted through cuts 22, the edges of battery 36 cause the strips of the circuit board to bend, creating a small hemispheric gap of approximately half a millimeter between battery 36 and the exposed areas on board 20, which prevents the LED from generating light. When a glass or bottle is placed on the coaster, the strips of board 20 are compressed causing areas 26 and 28 to contact the negative pole of battery 36, areas 40 and 42 to contact the positive pole of battery thus completing the circuit and causing LED 24 to generate light.

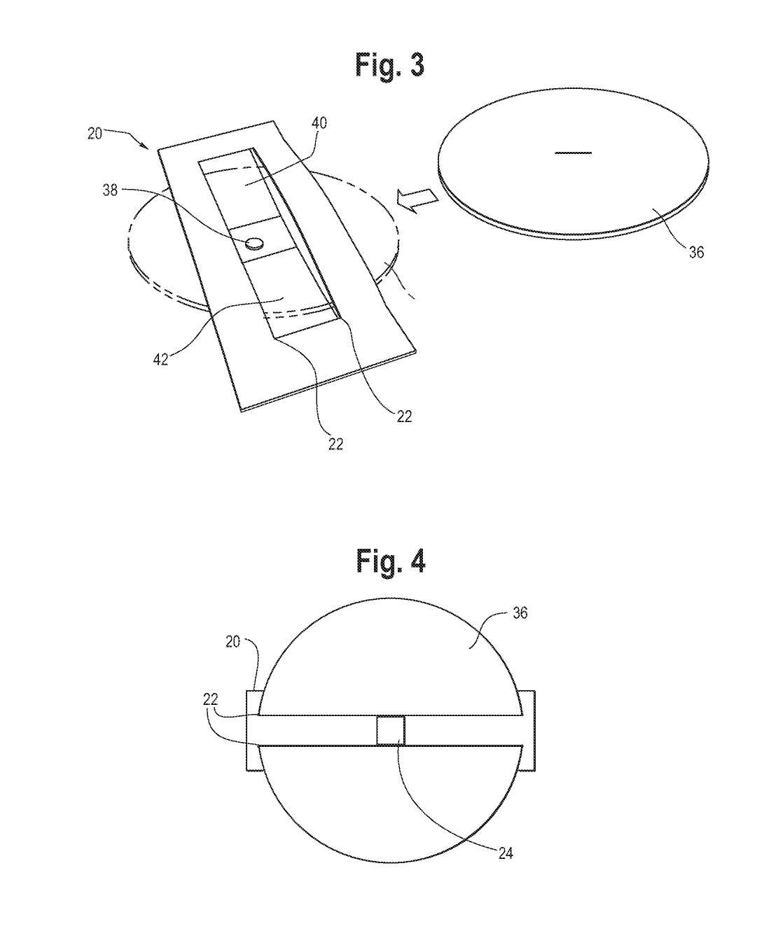

FIG. 3 depicts board 20 with the insertion of battery 36 through straight cuts 22 so that the center strip of board 20 is above battery 36 while side strips are below battery 36. In this way, conductive strips 26 and 28 are adjacent to the negative terminal of battery 36 while conductive strips 40 and 42 are adjacent to the positive terminal of battery 36. In operation, when a glass is placed on the coaster, conductive strips are brought into contact with the battery thus causing LED 24 to turn on.

Flexible circuit board 20 and battery 36 are sized so that they fit into the approximately 25 mm diameter hole in the lower body of FIG. 1B. In an embodiment, battery 36 is a type CR2016 button cell but any size or shape of flat battery may be used. After the board and batter assembly is inserted into the body of the coaster, a sticker or paper is placed or adhered over the assembly. This serves to retain the assembly within the body of the coaster. It also assists in the pressure sensitive operation of the LED switch.

If used and unless otherwise stated, the terms “upper,” “lower,” “front,” “back,” “over,” “under,” and similar such terms are not to be construed as limiting the invention to a particular orientation. Instead, these terms are used only on a relative basis.

The apparatus in one example comprises a plurality of components such as one or more of electronic components or hardware components. A number of such components can be combined or divided in the apparatus. The apparatus in one example comprises any (e.g., horizontal, oblique, or vertical) orientation, with the description and figures herein illustrating one example orientation of the apparatus, for explanatory purposes.

The steps or operations described herein are just for example. There may be many variations to these steps or operations without departing from the spirit of the invention. For instance, the steps may be performed in a differing order, or steps may be added, deleted, or modified.

Although example implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

What is claimed is:

1. A coaster for providing illumination to a liquid receptacle, comprising:
an upper body;
a lower body;
an LED (light emitting diode) inserted into an opening in said upper body;
an electronic device inserted in an opening in said lower body for providing power to the LED when a liquid receptacle is placed on the coaster.

2. The coaster of claim 1 wherein the electronic device further comprises a flexible circuit board and battery.

3. The coaster of claim 2 wherein the flexible circuit board further comprises soldering points for attaching the LED to the flexible circuit board.

4. The coaster of claim 2 wherein the flexible circuit board further comprises two conductive metal layers separated by a non-conductive layer.

5. The coaster of claim 4 wherein the flexible circuit board has a length and width, said flexible circuit board further comprising two slot-like openings along the length dimension that divide the flexible circuit board three strips having approximately equal widths.

6. The coaster of claim 5 wherein the battery is inserted through the slot-like openings and separates a middle strip of the flexible circuit board from two outer strips.

7. The coaster of claim 6 wherein the flexible circuit board is coated with a non-conductive material that has one or more areas where the metal layers of the flexible circuit board are exposed for making contact with the battery when a liquid receptacle is placed on the coaster.

8. The coaster of claim 1 wherein the opening in said upper body is approximately 4 mm in diameter and is located in a central portion of said upper body.

9. The coaster of claim 1 wherein the opening in the lower body approximately 25 mm in diameter and is aligned with the opening in the upper body.

10. The coaster of claim 1 wherein the upper and lower bodies are separate pieces of cardboard or foam and are fused together to form the coaster.

11. The coaster of claim 10 wherein the upper body is approximately 1 mm thick.

12. The coaster of claim 1 wherein the upper and lower bodies are a single piece of cardboard or foam.

13. The coaster of claim 1 wherein an upper surface of said upper body is capable of being printed.

14. The coaster of claim 1, wherein the upper and lower bodies have a square or circular outline.

15. The coaster of claim 1, wherein the upper and lower bodies have an irregular outline.

16. The coaster of claim 1 further comprising a thin sheet of paper adhered to the lower body for retaining the electronic device in the opening in the lower body.
